(19) United States
(12) Patent Application Publication
(10) Pub. No.: US 2018/0046990 A1
(43) Pub. Date: Feb. 15, 2018

(54) TRACKABLE BATTERY APPARATUS AND METHOD OF TRACKING SAME

(71) Applicant: Yung-Sheng HUANG, Taipei (TW)

(72) Inventor: Yung-Sheng HUANG, Taipei (TW)

(21) Appl. No.: 15/236,614

(22) Filed: Aug. 15, 2016

(51) Int. Cl. G06Q 10/00; G06Q 30/02; G01R 31/36; H04L 29/08

(52) U.S. Cl. CPC G06Q 10/30; H04L 67/10; G06Q 30/0201; G01R 31/3679; G01R 31/362

(57) ABSTRACT

A trackable battery apparatus (100) is provided with a control module (10); a power supply module (20) including a battery (21) for supplying power to the battery apparatus (100); a battery identification module (30) for generating an identification code (N) for identifying the battery apparatus (100); a battery tracking module (40) including a voltage sampling circuit (41) and a transient current control circuit (42) electrically connected to the battery (21) for generating a transient current wherein the voltage sampling circuit (41) samples an available capacity (h0) of the battery (21) on date of production, and an aging index (AX) is obtained by comparing the available capacity (h0) of the battery (21) on date of production to an available capacity of the battery (21) at a time of use; and an input/output (I/O) module (50) which sends the aging index (AX) and the identification code (N) to a cloud database (70).

### BACKGROUND OF THE INVENTION

### 1. Field of the Invention

The invention relates to battery recycling and more particularly to a trackable battery apparatus a method of tracking the trackable battery apparatus for recycling.

### 2. Description of Related Art

Waste batteries have a lot of plastic and metallic compounds or electrolyte solution. They can cause serious environmental pollution if not treated properly. Currently, garbage is disposed by landfill, incineration, composting, or other waste disposal means. However, waste batteries cannot be disposed by above garbage disposal. It is known that recyclable materials are contained in the used batteries and they include heavy metals which have high vale for recycling purposes. With environmental awareness among people, government's encouragement for recycling, taxes charged to battery manufacturers and importers, and subsidies to the recycling industry, the recycling rate of waste battery has increased greatly in recent years.

Currently, recycling of waste batteries is mainly done by users who send waste batteries to a recycling station. However, users are not sure whether the batteries are at its end of life or not. That is, good batteries may be sent for recycling. Further, the battery manufacturers do not know how many batteries are recycled after being produced because the battery is not trackable and no method is provided to track the consumed battery for cycling.

Thus, the need for improvement still exists.

### SUMMARY OF THE INVENTION

It is therefore one object of the invention to provide a trackable battery apparatus, comprising a control module including a microcontroller; a power supply module electrically connected to the control module and including a battery for supplying power to the battery apparatus; a battery identification module electrically connected to the control module for generating an identification code for identifying the battery apparatus; a battery tracking module electrically connected to the control module and including a voltage sampling circuit and a transient current control circuit electrically connected to positive and negative terminals of the battery for generating a transient current wherein the voltage sampling circuit is configured to sample an available capacity of the battery on a date of production, and an aging index is obtained by comparing the available capacity of the battery on a date of production to an available capacity of the battery at a time of use; and an input/output (I/O) module electrically connected to the control module and configured to send the aging index and the identification code to a cloud database for access.

It is another object of the invention to provide a method of tracking a trackable battery apparatus, comprising the steps of generating an identification code by the battery identification module when the trackable battery apparatus is manufacture on the date of production for identifying the trackable battery apparatus; measuring the available capacity of the battery on the date of production by the battery tracking module; sending the date of production, the identification code, an available capacity of the battery on the date of production to the cloud database for access; on the date of use the voltage sampling circuit sampling the battery to obtain a voltage; determining an aging state of the trackable battery apparatus on the date of use by using the aging index provide by the battery tracking module; sending the aging index to the cloud database for access; comparing a warning value to the aging index to obtain a comparison which is sent to the cloud database for access; alerting the trackable battery apparatus to be ready to recycle if the aging index is less than the warning value; in recycling, sending a recycling date of the trackable battery apparatus an the identification code of the trackable battery apparatus to the cloud database as a record; and confirming that the trackable battery apparatus has been recycle by retrieving the recycling date an the identification code of the trackable battery apparatus by accessing the cloud database.

Thus, the first aspect of the present invention is a trackable battery apparatus, comprising: a control module including a microcontroller; a power supply module electrically connected to the control module and including a battery for supplying power to the battery apparatus; a battery identification module electrically connected to the control module for generating an identification code (N) for identifying the battery apparatus; a battery tracking module electrically connected to the control module and including a voltage sampling circuit and a transient current control circuit electrically connected to positive and negative terminals of the battery for generating a transient current wherein the voltage sampling circuit is configured to sample an available capacity (h0) of the battery on a date of production, and an aging index (AX) is obtained by comparing the available capacity (h0) of the battery on a date of production to an available capacity (h1) of the battery at a time of use; and an input/output (I/O) module electrically connected to the control module and configured to send the aging index (AX) and the identification code (N) to a cloud database for access.

According to an embodiment of the present invention, the available capacity (h0) of the battery on a date of production (D0) is obtained by deducting a voltage (V01) sampled by the voltage sampling circuit when the transient current control circuit generates a transient current at a turning point on the date of production (D0) from a reference voltage (V02) on the date of production (D0), the available capacity (h0) of the battery is sent to the cloud database, and after waiting a period of time, the voltage sampling circuit samples the battery to obtain a voltage.

According to an embodiment of the present invention, on a date of use (D1) when the transient current control circuit generates the transient current at the turning point and the voltage sampling circuit samples the battery to obtain a voltage (V11) at a turning point on a date of use, wherein after waiting a period of time, the voltage sampling circuit samples the battery to obtain a reference voltage (V12) on the date of use, the battery tracking module calculates a difference between the voltage (V11) at the turning point and the reference voltage (V12) on the date of use to obtain an available capacity (h1) of the battery, and the aging index (AX) is obtained by comparing the available capacity (h0) of the battery on the date of production (D0) to the available capacity (h1) of the battery, and wherein the aging index (AX) is sent to the cloud database for access.

According to an embodiment of the present invention, a warning value is compared to the aging index (AX), the trackable battery apparatus is configured to recycle if the aging index (AX) is less than the warning value, and a recycling date (D2) of the trackable battery apparatus and the identification code (N) of the trackable battery apparatus are sent to the cloud database as a record.

According to an embodiment of the present invention, the transient current control circuit includes a metal-oxide-semiconductor field-effect transistor (MOSFET) (Q1) paralleled the battery, and the MOSFET (Q1) is controlled by the microcontroller to serve as a switch.

According to an embodiment of the present invention, the I/O module includes a wireless transmission unit implemented as Wi-Fi, Bluetooth device, or near-field communication for accessing the cloud database.

According to an embodiment of the present invention, the I/O module includes a wire transmission unit implemented as an integrated circuit, a serial peripheral interface bus, a universal asynchronous receiver/transmitter, a universal serial bus (USB) connector, or an RS-232 serial port for accessing the cloud database.

According to an embodiment of the present invention, further comprising a display module for displaying a quick response (QR) code which stores the aging index (AX) and the identification code (N) so that the AR code and the aging index (AX) can be accessed by decoding the QR code.

According to an embodiment of the present invention, the identification code (N) is related to the date of production (D0) for confirming the trackable battery apparatus being manufactured on the date of production (D0).

The second aspect of the present invention is a method of tracking a trackable battery apparatus comprising the steps of:

(1) generating an identification code (N) by the battery Identification module when the trackable battery apparatus is manufactured on the date of production (D0) for identifying the trackable battery apparatus;

(2) measuring the available capacity (h0) of the battery on the date of production (D0) by the battery tracking module;

(3) sending the date of production (D0), the identification code (N), and the available capacity (h0) of the battery on the date of production (D0) to the cloud database for access;

(4) sampling the battery to obtain a voltage (V11), on the date of use (D1) by the voltage sampling circuit;

(5) determining an aging state of the trackable battery apparatus on the date of use (D1) by using the aging index (AX) provided by the battery tracking module;

(6) sending the aging index (AX) to the cloud database for access;

(7) comparing a warning value to the aging index (AX) to obtain a comparison which is sent to the cloud database for access;

(8) alerting the trackable battery apparatus to be ready to recycle if the aging index (AX) is less than the warning value;

(9) in recycling, sending a recycling date (D2) of the trackable battery apparatus and the identification code (N) of the trackable battery apparatus to the cloud database as a record; and

(10) confirming that the trackable battery apparatus has been recycled by retrieving the recycling date (D2) and the identification code (N) of the trackable battery apparatus by accessing the cloud database.

The above and other objects, features and advantages of the invention will become apparent from the following detailed description taken with the accompanying drawings.

### BRIEF DESCRIPTION OF THE DRAWINGS

FIG. 1 is a block diagram of a trackable battery apparatus according to the invention;

FIG. 2 is a block and circuit diagram of the trackable battery apparatus;

FIG. 3 plots a voltage curve of sampled voltage values;

FIG. 4 plots a voltage curve of another sampled voltage values;

FIG. 5 is a flow chart of a method of tracking a trackable battery apparatus according to the invention; and

FIG. 6 depicts different user ends connected to the cloud database of FIG. 5.

### DETAILED DESCRIPTION OF THE INVENTION

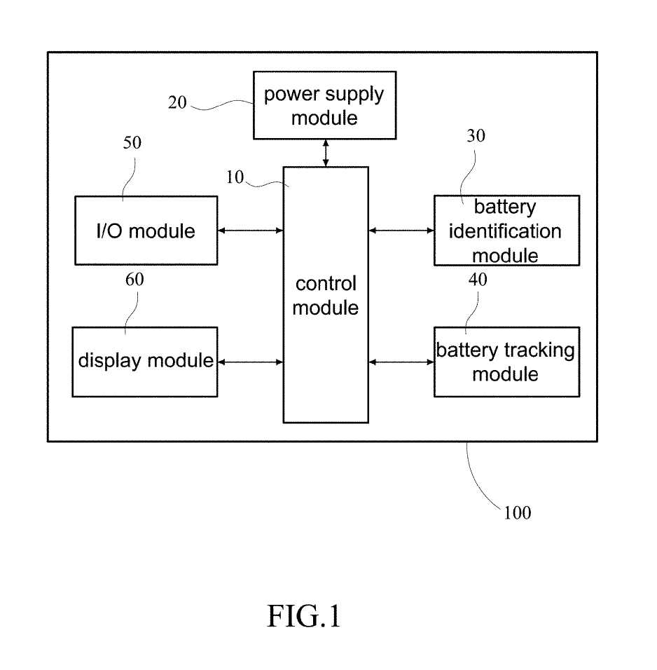

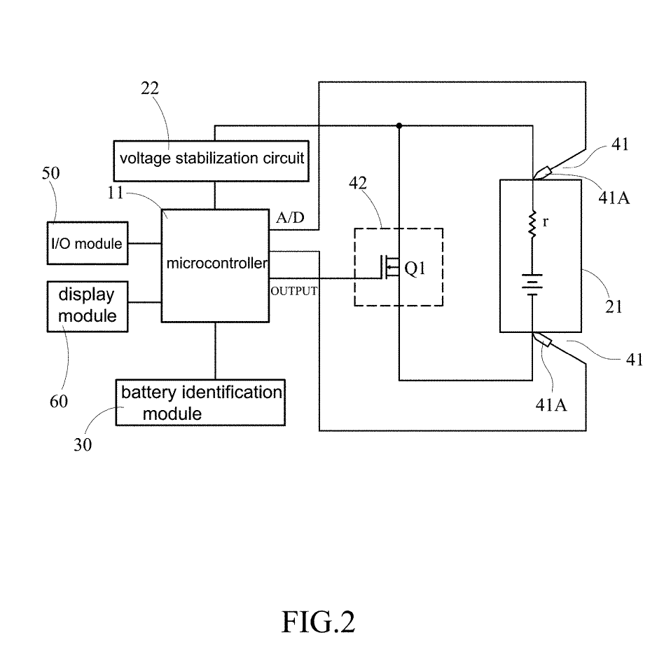

Referring to FIGS. 1 to 4 and 6, a trackable battery apparatus 100 in accordance with the invention comprises the following components as discussed in detail below.

A control module 10, a power supply module 20, a battery identification module 30, a battery tracking module 40, an input/output (I/O) module 50 and a display module 60 are provided. The control module 10 includes a microcontroller 11 electrically connected to the power supply module 20, the battery identification module 30, the battery tracking module 40, the I/O module 50 and the display module 60 respectively so that the microcontroller 11 can control the power supply module 20, the battery identification module 30, the battery tracking module 40, the I/O module 50 and the display module 60 respectively.

The power supply module 20 includes a voltage stabilization circuit 22 and a battery 21 for supplying power to all components of the trackable battery apparatus 100 via the voltage stabilization circuit 22. The battery identification module 30 is electrically connected to the control module 10 and configured to generate an identification code (N) which is unique. The trackable battery apparatus 100 can be identified by the identification code (N). The battery tracking module 40 electrically connected to the control module 10 includes a voltage sampling circuit 41 and a transient current control circuit 42. The voltage sampling circuit 41 includes two sampling circuit terminals 41A in which one is electrically interconnected an analog/digital (A/D) terminal of the microcontroller 11 and a positive terminal of the battery 21 and the other is electrically interconnected the microcontroller 11 and a negative terminal of the battery 21.

The transient current control circuit 42 includes a metal-oxide-semiconductor field-effect transistor (MOSFET) Q1 paralleled the battery 21. The MOSFET Q1 is controlled by the microcontroller 11 to serve as a switch. The MOSFET Q1 and associated circuits thereof are loads. Further, the MOSFET Q1 serves to limit transient current. Voltage values are sampled by sampling a transient current of the battery 21. Moreover, external resistor(s) can be provided to parallel the battery 21 as a load. The trackable battery apparatus 100 can track the battery 21 by using the battery tracking module 40. Further, the trackable battery apparatus 100 can be identified by using the identification code (N). For example, the trackable battery apparatus 100 is manufactured on a date D0 and has the most recently used date D1. The condition of the battery 21 can be tracked by using the battery tracking module 40.

The transient current control circuit 42 is controlled by the microcontroller 11 to conduct the MOSFET Q1 which in turn generates a transient current. The voltage sampling circuit 41 samples a voltage V01 at turning point and a reference voltage V02 at stable manner. Maximum capacity (state of charge) of the battery 21 on the date of production is labeled as h0. Available capacity (state of charge) of the battery 21 after use (labeled as h1) is compared to h0 to obtain an aging index AX.

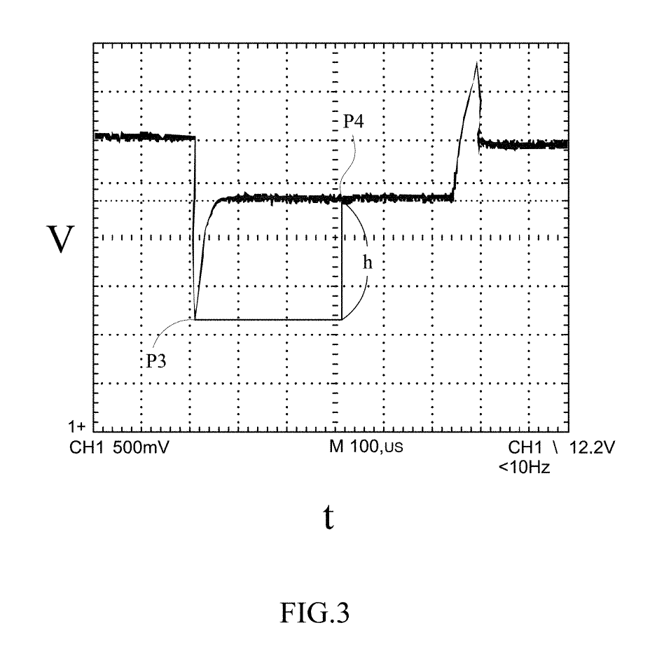

In the voltage/time curve of FIG. 3, the voltage V01 at turning point represents a minimum voltage across positive and negative terminals of the battery 21 having a date of production D0 (i.e., voltage at a turning point P3) when the MOSFET Q1 is conducted by the transient current control circuit 42. The reference voltage V02 is a voltage at a reference point P4 which is above the lowest point (i.e., the turning point P3) by a height (h). The turning point P3 is taken as a reference. The height (h) can be used for determining the remaining capacity of the battery 21.

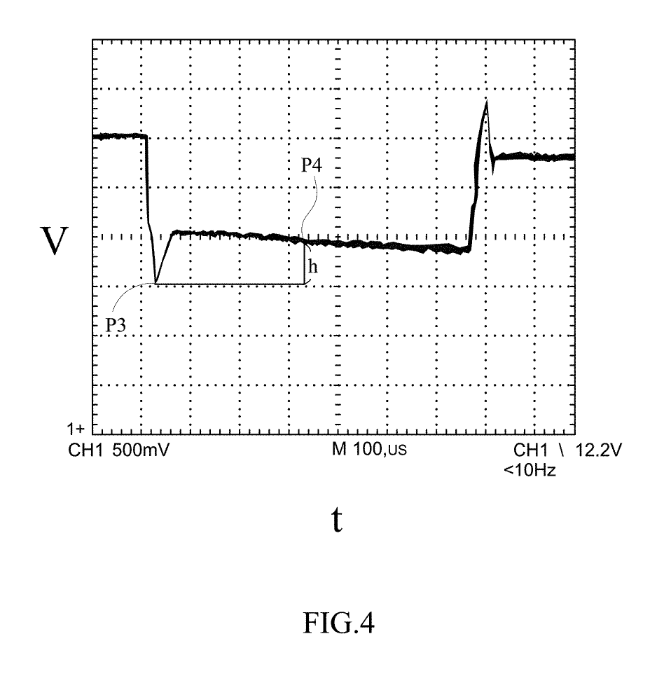

In FIG. 4, the reference point P4 is above the turning point P3 by a height (h) which is less than the height (h) of FIG. 3. Thus, the remaining capacity of the battery 21 in FIG. 4 is less than that of the battery 21 in FIG. 3. This is because the battery 21 in FIG. 4 is used more times than that in FIG. 3.

The I/O module 50 includes a wireless transmission unit for sending the aging index AX, the identification code (N), and the date of production D0 to a cloud database 70 so that a user may retrieve the aging index AX, the identification code (N), and the date of production D0 by accessing the cloud battery 70. The wireless transmission unit is Wi-Fi, Bluetooth device, or near-field communication. Alternatively, the I/O module 50 is replaced by a wire transmission unit which can be an integrated circuit, a serial peripheral interface bus, a universal asynchronous receiver/transmitter, a universal serial bus (USB) connector, or an RS-232 serial port and can access the cloud database 70. The display module 60 can display a quick response (QR) code and store the aging index AX, the identification code (N), and the date of production D0 in the QR code. Thus, a user may retrieve the aging index AX, the identification code (N), and the date of production D0 by using the QR code.

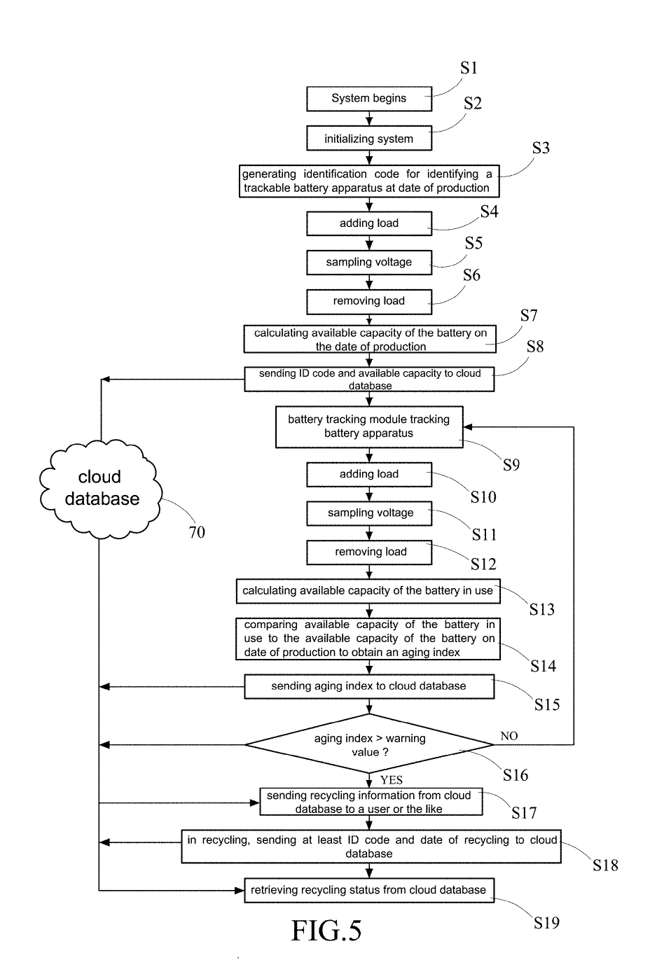

Referring to FIG. 5 in conjunction with FIGS. 1 to 4 and 6, a flow chart of a method of tracking the trackable battery apparatus 100 in accordance with the invention is illustrated. The method comprises the following steps:

Step S1: System begins with vector addresses being interrupted and software begins to run.

Step S2: System is initialized with registers and I/O pins initialized, the registers reset, interrupt vectors and timers activated, and states and initial values of each I/O pin defined.

Step S3: A unique identification code (N) is generated by a battery Identification module 30 when the trackable battery apparatus 100 is manufactured. The identification code (N) is used to identify a specific trackable battery apparatus 100.

Step S4: Load is added to the system. The microcontroller 11 activates a transient current control circuit 42 to conduct the MOSFET Q1 which in turn generates a transient current.

Step S5: Voltage is sampled. The voltage sampling circuit 41 measures the voltage at the turning point P3 when the trackable battery apparatus 100 being produced and the reference voltage at the reference point P4. Also, a transient current is generated by the transient current control circuit 42 at the date of production D0. The voltage sampling circuit 41 measures the voltage V01 at turning point and also the reference voltage V02 at stable manner when the trackable battery apparatus 100 is being produced. Step S6: Load is removed. The microcontroller 11 deactivates the transient current control circuit 42 to turn off the MOSFET Q1.

Step S7: The battery tracking module 40 calculates a difference between the voltage at turning point and the reference voltage at stable manner so as to obtain an available capacity of the battery on the date of production D0. Specifically, the battery tracking module 40 calculates a difference between the voltage V01 at turning point and the reference voltage V02 at stable manner so as to obtain an available capacity h0 of the battery 21 in the trackable battery apparatus 100 on the date of production D0.

Step S8: Additionally, the I/O module 50 sends the identification code (N) and available capacity h0 of the battery 21 to a cloud database 70 as a record.

Step S9: The battery tracking module 40 may track the trackable battery apparatus 100.

Step S10: Load is added to the system. The microcontroller 11 activates the transient current control circuit 42 to conduct the MOSFET Q1 which in turn generates a transient current.

Step S11: The voltage sampling circuit 41 measures the voltage at turning point and the reference voltage. Specifically, a user may activate the transient current control circuit 42 to generate a transient current at date D1 and activate the voltage sampling circuit 41 to measures the voltage V11 at turning point, and the reference voltage V12 at stable manner.

Step S12: Load is removed. The microcontroller 11 deactivates the transient current control circuit 42 to turn off the MOSFET Q1.

Step S13: The battery tracking module 40 calculates a difference between the voltage at turning point and the reference voltage at stable manner, so as to obtain an available capacity of the battery on the date of use D1. That is, the battery tracking module 40 calculates a difference between the voltage V11 at the turning point and the reference voltage V12 at stable manner, so as to obtain an available capacity h1 of the battery 21 in the trackable battery apparatus 100 on the date of use D1.

Step S14: Available capacity of the battery after use is compared to the available capacity to obtain an aging index. Specifically, available capacity h1 of the battery 21 on the date of use D1 is divided by the available capacity h0 on the date of production to obtain an aging index AX in terms of percentage for determining the aging state of the battery 21.

Step S15: Aging index is sent to the cloud database. Specifically, the I/O module 50 sends the aging index AX to the cloud database 70 by means of wireless or wire medium. A user or the like may access the cloud database 70 to retrieve the identification code (N) which is in turn used to retrieve the aging index AX.

Step S16: It is determined whether recycling of the battery is necessary based on a warning value from the manufacturer. Specifically, the aging index AX is compared to the warning value. The comparison result and the identification code (N) are sent to the cloud database 70. The flow chart goes to step S17 if the comparison is positive. Otherwise, the flow chart returns to step S9.

Step S17: Sending battery recycling information. Specifically, information of the trackable battery apparatus 100 having a consumed battery 21 is sent from the cloud database 70 to a user or the like.

Step S18: Battery recycled. A trackable battery apparatus 100 having the identification code (N) is sent to a recycling station. Further, the identification code (N) and the recycling date D2 are sent to the cloud database 70 as a record.

Step S19: Recycling status. Specifically, a battery user, a battery manufacturer, a recycling company, or an environmental protection agency in charge of battery recycling may be aware of the recycling status of a recycled trackable battery apparatus 100 by accessing the cloud database 70 to retrieve the identification code (N) and the recycling date D2 of the trackable battery apparatus 100.

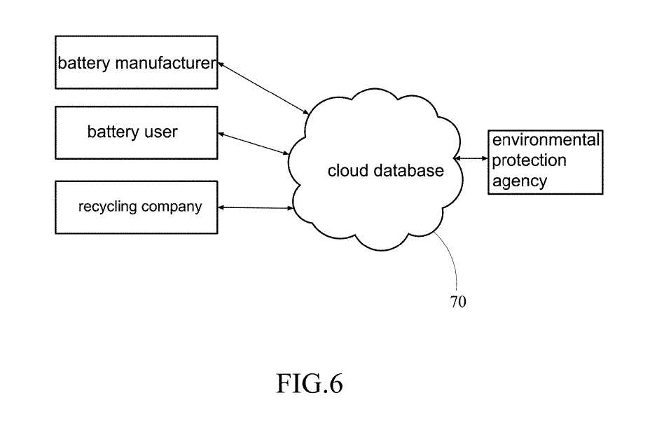

Referring to FIG. 6 specifically, a battery user, a battery manufacturer, a recycling company, and an environmental protection agency in charge of battery recycling are capable of accessing the cloud database 70 to retrieve information about a recycled battery.

While the invention has been described in terms of preferred embodiments, those skilled in the art will recognize that the invention can be practiced with modifications within the spirit and scope of the appended claims.

What is claimed is:

1. A trackable battery apparatus, the tractable battery apparatus (100) comprising:
a control module (10) including a microcontroller (11);
a power supply module (20) electrically connected to the control module (10) and including a battery (21) for supplying power to the battery apparatus (100);
a battery identification module (30) electrically connected to the control module (10) for generating an identification code (N) for identifying the battery apparatus (100);
a battery tracking module (40) electrically connected to the control module (10) and including a voltage sampling circuit (41) and a transient current control circuit (42) electrically connected to positive and negative terminals of the battery (21) for generating a transient current wherein the voltage sampling circuit (41) is configured to sample an available capacity (h0) of the battery (21) on a date of production, and an aging index (AX) is obtained by comparing the available capacity (h0) of the battery (21) on a date of production to an available current of the battery (21) at a time of use; and
an input/output (I/O) module (50) electrically connected to the control module (10) and configured to send the aging index (AX) and the identification code (N) to a cloud database (70) for access.

2. The trackable battery apparatus of claim 1, wherein the available capacity (h0) of the battery (21) on a date of production (D0) is obtained by deducting a voltage (V01) at the turning point sampled by the voltage sampling circuit (41) when the transient current control circuit (42) generates a transient current at a turning point on the date of production (D0) from a reference voltage (V02) on the date of production (D0), the available capacity (h0) of the battery (21) is sent to the cloud database (70), and after waiting a period of time, the voltage sampling circuit (41) samples the battery (21) to obtain a stable voltage.

3. The trackable battery apparatus of claim 1, wherein on a date of use (D1) when the transient current control circuit (42) generates the transient current at the turning point and the voltage sampling circuit (41) samples the battery (21) to obtain a voltage (V11) at a turning point on a date of use, wherein after waiting a period of time, the voltage sampling circuit (41) samples the battery (21) to obtain a reference voltage (V12) on the date of use, the battery tracking module (40) calculates a difference between the voltage (V11) at the turning point and the reference voltage (V12) on the date of use to obtain an available capacity (h1) of the battery (21), and the aging index (AX) is obtained by comparing the available capacity (h0) of the battery (21) on the date of production (D0) to the available capacity (h1) of the battery (21), and wherein the aging index (AX) is sent to the cloud database (70) for access.

4. The trackable battery apparatus of claim 3, wherein a warning value is compared to the aging index (AX), the trackable battery apparatus (100) is configured to recycle if the aging index (AX) is less than the warning value, and a recycling date (D2) of the trackable battery apparatus (100) and the identification code (N) of the trackable battery apparatus (100) are sent to the cloud database (70) as a record.

5. The trackable battery apparatus of claim 1, wherein the transient current control circuit (42) includes a metal-oxide-semiconductor field-effect transistor (MOSFET) (Q1) paralleled the battery (21), and the MOSFET (Q1) is controlled by the microcontroller (11) to serve as a switch.

6. The trackable battery apparatus of claim 1, wherein the I/O module (50) includes a wireless transmission unit implemented as Wi-Fi, Bluetooth device, or near-field communication for accessing the cloud database (70).

7. The trackable battery apparatus of claim 1, wherein the I/O module (50) includes a wire transmission unit implemented as an integrated circuit, a serial peripheral interface bus, a universal asynchronous receiver/transmitter, a universal serial bus (USB) connector, or an RS-232 serial port for accessing the cloud database (70).

8. The trackable battery apparatus of claim 1, further comprising a display module (60) for displaying a quick response (QR) code which stores the aging index (AX) and the identification code (N) so that the AR code and the aging index (AX) can be accessed by decoding the QR code.

9. The trackable battery apparatus of claim 1, wherein the identification code (N) is related to the date of production (D0) for confirming the trackable battery apparatus (100) being manufactured on the date of production (D0).

10. The trackable battery apparatus of claim 8, wherein the identification code (N) is related to the date of production (D0) for confirming the trackable battery apparatus (100) being manufactured on the date of production (D0).

11. A method of tracking the trackable battery apparatus of claim 1, comprising the steps of:
(1) generating an identification code (N) by the battery Identification module (30) when the trackable battery apparatus (100) is manufactured on the date of production (D0) for identifying the trackable battery apparatus (100);
(2) measuring the available capacity (h0) of the battery (21) on the date of production (D0) by the battery tracking module (40);
(3) sending the date of production (D0), the identification code (N), and the available capacity (h0) of the battery (21) on the date of production (D0) to the cloud database (70) for access;
(4) sampling the battery (21) to obtain a voltage (V11), on the date of use (D1) by the voltage sampling circuit (41);
(5) determining an aging state of the trackable battery apparatus (100) on the date of use (D1) by using the aging index (AX) provided by the battery tracking module (40);
(6) sending the aging index (AX) to the cloud database (70) for access;
(7) comparing a warning value to the aging index (AX) to obtain a comparison which is sent to the cloud database (70) for access;
(8) alerting the trackable battery apparatus (100) to be ready to recycle if the aging index (AX) is less than the warning value;
(9) in recycling, sending a recycling date (D2) of the trackable battery apparatus (100) and the identification code (N) of the trackable battery apparatus (100) to the cloud database (70) as a record; and
(10) confirming that the trackable battery apparatus (100) has been recycled by retrieving the recycling date (D2) and the identification code (N) of the trackable battery apparatus (100) by accessing the cloud database (70).
